(19) United States
(12) Patent Application Publication
(10) Pub. No.: US 2013/0224944 A1
(43) Pub. Date: Aug. 29, 2013

(54) METHODS FOR FABRICATING INTEGRATED CIRCUITS USING TAILORED CHAMFERED GATE LINER PROFILES

(71) Applicants: Puneet Khanna, Wappingers Falls, NY (US); Dae-han Choi, Wappingers Falls, NY (US); Katherina Babich, Cold Springs, NY (US); Catherine Labelle, Wappingers Falls, NY (US)

(72) Inventors: Puneet Khanna, Wappingers Falls, NY (US); Dae-han Choi, Wappingers Falls, NY (US); Katherina Babich, Cold Springs, NY (US); Catherine Labelle, Wappingers Falls, NY (US)

(73) Assignee: GLOBALFOUNDRIES Inc., Grand Cayman (KY)

(21) Appl. No.: 13/405,414

(22) Filed: Feb. 27, 2012

(51) Int. Cl. H01L 21/28

(52) U.S. Cl. 438/595; 257/E21.19

(57) ABSTRACT

Methods for fabricating integrated circuits using tailored chamfered gate liner profiles are provided. In an exemplary embodiment, a method for fabricating an integrated circuit includes forming a dummy gate electrode overlying a semiconductor substrate and forming a liner on sidewalls of the dummy gate electrode. A dielectric material is deposited overlying the dummy gate electrode, the liner, and the substrate. The dummy gate electrode is exposed by chemical mechanical planarization. A portion of the dummy gate electrode is removed and the liner is isotropically etched such that it has a chamfered surface. A remainder of the dummy gate electrode is removed to form an opening that is filled with a metal.

### TECHNICAL FIELD

The present invention generally relates to methods for fabricating integrated circuits, and more particularly relates to methods for fabricating integrated circuits using tailored chamfered gate liner profiles.

### BACKGROUND

The semiconductor industry is continuously moving toward the fabrication of larger and more complex integrated circuits (ICs). As integrated circuits become larger, the size of individual components making up those ICs and the minimum feature size (minimum line width or spacing) of those components gets smaller. Smaller feature sizes increase processing complexity, difficulty, and reliability in various ways.

The ability to reliably fill deep, narrow (i.e., high aspect ratio) openings with metal, for example, is one such complexity. High aspect ratio openings occur, for example, in providing metal gates in a replacement gate technology. FIG. 1 illustrates a high aspect ratio opening 4 of a field effect transistor (FET) IC 2. The high aspect ratio opening is created upon removal of a dummy gate electrode (not shown) that was formed overlying a semiconductor substrate 6. In conventional replacement gate technology, the dummy gate electrode is formed, followed by the formation of spacers or liners 8 adjacent the sidewalls of the dummy gate electrode. A dielectric material layer 10 then is formed overlying the dummy gate electrode and the sidewall spacers 8. A portion of the dielectric material layer 10 is removed to expose the dummy gate electrode, which is removed to form the opening 4. A permanent gate electrode is formed by depositing a metal 12 in the opening 4. Other materials (not shown) such as gate insulator material, barrier layer material, and work function metal may be deposited in the opening before the metal is deposited.

As the metal 12 is deposited in the high aspect ratio opening, the metal begins to deposit unevenly in the opening, accumulating at the mouth of the opening and causing “bumps” or “shelves” 14 to form at the mouth, as illustrated in FIG. 2. As deposition of the metal continues, these “bumps” or “shelves” 14 eventually make contact at the mouth and squeeze off the opening, leaving a pocket of air or “void” 16 within the opening, as illustrated in FIG. 3. Such voids in the field effect transistor can result in failure of the device.

Accordingly, it is desirable to provide methods for fabricating integrated circuits having narrow, metal filled openings. Furthermore, other desirable features and characteristics of the present invention will become apparent from the subsequent detailed description and the appended claims, taken in conjunction with the accompanying drawings and the foregoing technical field and background.

### BRIEF SUMMARY

Methods for fabricating integrated circuits using tailored chamfered gate liner profiles are provided. In accordance with an exemplary embodiment, a method for fabricating an integrated circuit includes forming a dummy gate electrode overlying a semiconductor substrate and forming a liner on sidewalls of the dummy gate electrode. A dielectric material is deposited overlying the dummy gate electrode, the liner, and the semiconductor substrate. The dummy gate electrode is exposed by chemical mechanical planarization. A portion of the dummy gate electrode is removed and the liner is isotropically etched such that the liner has a chamfered surface. A remainder of the dummy gate electrode is removed to form an opening and the opening is filled with a metal.

In accordance with another exemplary embodiment, a method for fabricating an integrated circuit includes providing a dielectric layer overlying a semiconductor substrate. The dielectric layer has an opening with sidewalls, a sacrificial material is positioned within the opening, and a liner is interposed between the sidewalls of the opening and the sacrificial material. A portion of the sacrificial material and the liner is etched so that the liner has a chamfered surface. A remainder of the sacrificial material is removed leaving a second opening and a permanent material is deposited in the second opening.

In accordance with a further exemplary embodiment, a method for fabricating an integrated circuit includes forming a dummy gate electrode overlying a semiconductor substrate, forming a liner on sidewalls of the dummy gate electrode, and depositing a dielectric material overlying the dummy gate electrode, the liner, and the semiconductor substrate. The dummy gate electrode is exposed by chemical mechanical planarization. A portion of the dummy gate electrode is removed and a chamfered surface of the liner is formed. A remainder of the dummy gate electrode is removed to form an opening and a permanent gate electrode is formed in the opening. After removing the remainder of the dummy gate electrode and before forming the permanent gate electrode, the chamfered surface of the liner forms an angle with a top surface of the dielectric material that is in a range of about 30 to about 60 degrees.

### BRIEF DESCRIPTION OF THE DRAWINGS

The present invention will hereinafter be described in conjunction with the following drawing figures, wherein like numerals denote like elements, and wherein:

FIGS. 1-3 illustrate, via cross-sectional views, conventional method steps for filling a high aspect ratio opening with metal during which a void is formed; and

FIGS. 4-12 illustrate, via cross-sectional views, method steps for fabricating an integrated circuit in accordance with various embodiments.

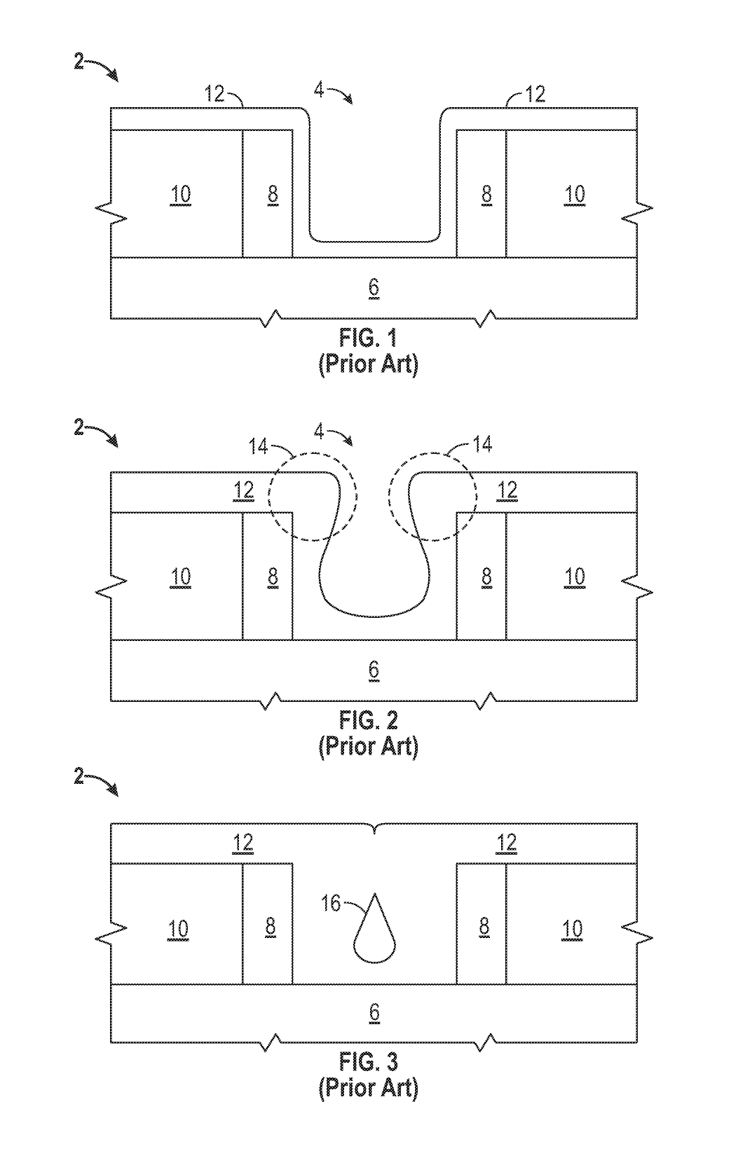

### DETAILED DESCRIPTION

The following detailed description is merely exemplary in nature and is not intended to limit the invention or the application and uses of the invention. Furthermore, there is no intention to be bound by any theory presented in the preceding background or the following detailed description.

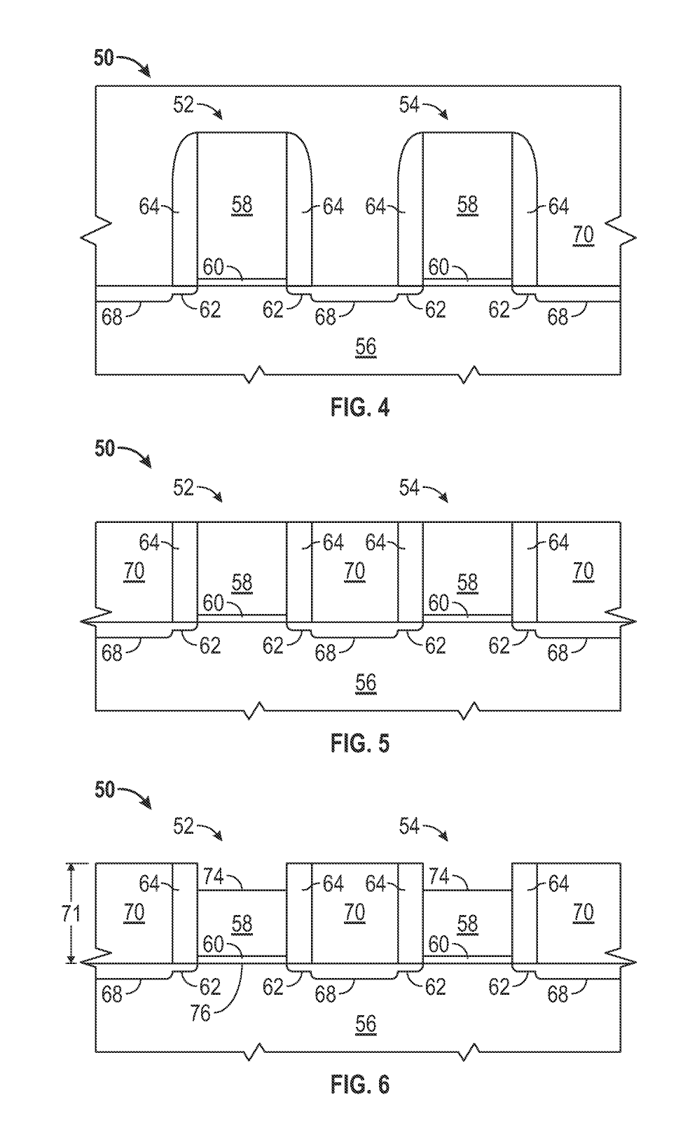

FIGS. 4-12 schematically illustrate, in cross section, methods for fabricating integrated circuits in accordance with various embodiments. The methods include steps for reliably filling narrow openings. The methods are particularly applicable to forming replacement metal gates of FET ICs, and will be so illustrated in exemplary embodiments, but the methods are not limited to such applications. The methods described herein are applicable to the filling of any opening with a material, for example, filling an opening with dielectric material, such as tetraethylorthosilicate, via chemical vapor deposition. Various steps in the fabrication of FET semiconductor integrated circuits are well known and so, in the interest of brevity, many conventional fabrication steps will only be mentioned briefly herein or will be omitted entirely without providing the well-known process details.

FIG. 4 illustrates a portion of an IC 50, specifically a FET IC, at an early stage in its fabrication. Only a portion of IC 50 is shown, and that portion includes a plurality of spaced-apart dummy gate structures 52 and 54 (only two of which are illustrated) formed overlying a semiconductor substrate 56. The semiconductor substrate can be silicon, silicon admixed with germanium or other elements, or other semiconductor materials such as germanium commonly used for the fabrication of ICs, and can be either a bulk semiconductor wafer or a thin layer of semiconductor material on an insulating layer (SOI). Although not illustrated, substrate 56 can be selectively doped with conductivity-determining impurities, for example by ion implantation, to form doped wells or regions. Shallow trench isolation (STI) (not shown) or other forms of isolation may be formed in the substrate to provide electrical isolation between various regions as required by the circuit being implemented.

In accordance with an embodiment, a thin layer of insulating material is grown or deposited overlying the semiconductor substrate 56, a layer of dummy gate electrode material, such as polycrystalline or amorphous silicon, is deposited overlying the insulating material, and both are patterned to form the dummy gate structures 52, 54, each having a dummy gate electrode 58 and a dummy gate insulator 60, as illustrated in FIG. 4. Dummy gate electrode 58 is used as an ion implantation mask and conductivity-determining ions, such as boron or phosphorous ions, are implanted into substrate 56 to form source and drain extensions 62 in self-alignment with the dummy gate electrode. Although not illustrated, halo implants may also be carried out using the dummy gate electrode as an implantation mask. Sidewall liners 64 are formed on the walls of dummy gate electrode 58. The sidewall liners can be formed, for example, by depositing and anisotropically etching, for example by reactive ion etching (RIE), a layer of sidewall liner material such as a layer of a silicon oxide or a silicon nitride. The dummy gate electrode and the sidewall liners are then used as an ion implantation mask and conductivity-determining ions such as boron ions or phosphorous ions are implanted into substrate 56 to form deep source and drain regions 68, again in self-alignment with dummy gate electrode 58. Alternatively, source and drain regions can be formed as raised source and drain regions by epitaxially growing a silicon-containing material overlying a silicon-containing semiconductor substrate 56 while doping the material with a dopant species in the reactant gases. A dielectric material 70 is deposited overlying the dummy gate structures 52, 54 and the semiconductor substrate 56. The dielectric material 70 has a composition different than the composition of the sidewall liners 64. For example, the dielectric material 70 can be deposited by chemical vapor deposition (CVD) from a tetraethyl orthosilicate (TEOS) source. Referring to FIG. 5, a portion of the dielectric material 70 is removed, such as by, for example, chemical mechanical planarization (CMP), to expose the dummy gate electrodes 58. A portion of sidewall liners 64 and dummy gate electrodes 58 also may be removed during the CMP process.

The method continues, as illustrated in FIG. 6, with the partial etching of dummy gate electrodes 58. The dummy gate electrodes are etched with an etchant that has very high selectivity for the materials that form the sidewall liners 64 and the dielectric material 70. In an exemplary embodiment, the dummy gate electrodes are formed of polycrystalline silicon, the dielectric material is of a silicon oxide, the sidewall liners are formed of a silicon nitride, and the etchant used to etch dummy gate electrodes 58 includes hydrogen bromide (HBr), chlorine (Cl₂), sulfur hexafluoride (SF₆), nitrogen trifluoride (NF₃), tetramethylammonium hydroxide (TMAH), tetraethylammonium hydroxide (TEAH), ammonium hydroxide, or combinations thereof. In an embodiment, the dummy gate electrodes are etched to remove about 10 to about 15 percent of the initial height, indicated by double-headed arrow 71, of the dummy gate electrode from a top surface 74 of the dummy gate electrode. As used herein, the “top surface” of the dummy gate electrode 58 is that surface of the dummy gate electrode that is parallel to but most remote from a surface 76 of semiconductor substrate 56. In another embodiment, about 5 to about 20 nanometers (nm) is removed from the top surface of the dummy gate electrodes 58.

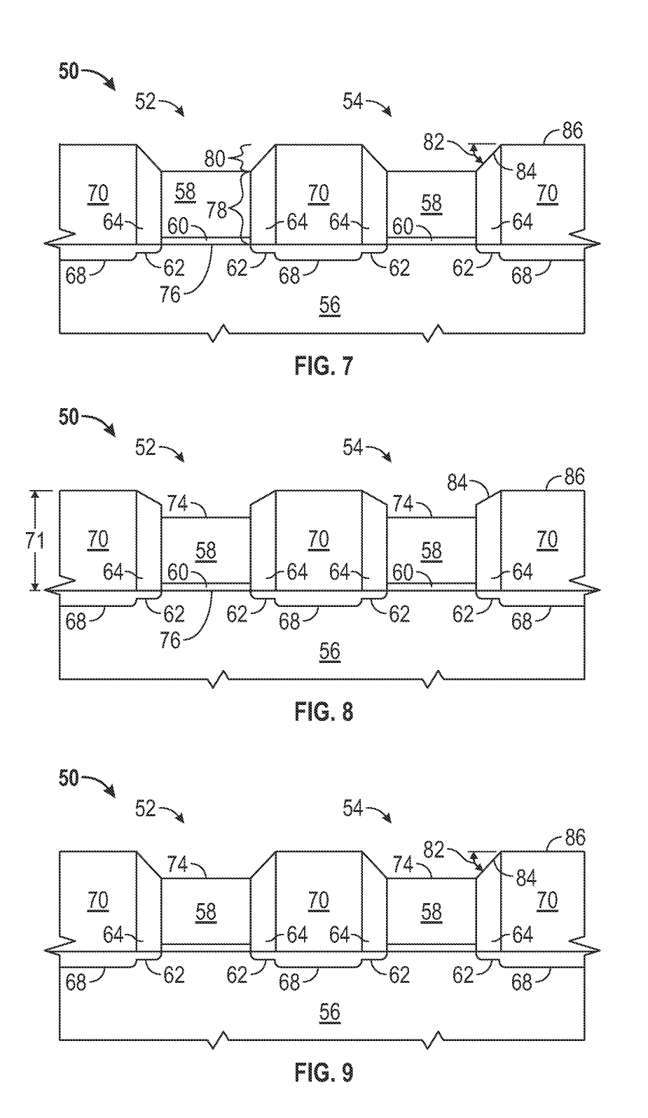

Next, an isotropic etch of the sidewall liners 64 is performed so that the sidewall liners achieve a chamfered profile. As a portion 78 of the sidewall liners 64 is covered by the dummy gate electrode 58 and the dummy gate insulator 60 and, thus, protected from the etchant, only an exposed portion 80 of the sidewall liners is etched. The sidewall liners are etched with an etchant that has very high selectivity for the materials that form the dummy gate electrodes 58 and the dielectric material 70. In an exemplary embodiment, the dummy gate electrodes are formed of polycrystalline silicon, the dielectric material is of a silicon oxide, the sidewall liners are formed of a silicon nitride, and the etchant used to etch sidewall liners is phosphoric acid. As illustrated in FIG. 7, a chamfered surface 84 of the sidewall liner 64 forms an angle 82 with a top surface 86 of the dielectric material 70. As used herein, the “top surface” of the dielectric material 70 is that surface of the dielectric material that is parallel to but most remote from the surface 76 of semiconductor substrate 56.

In an optional embodiment, a second partial etch of the dummy gate electrodes 58 is performed, as illustrated in FIG. 8. The dummy gate electrodes can be etched with the same etchant as used in the etching process described above with reference to FIG. 6, or a different etchant with high selectivity for the materials that form the sidewall liners 64 and the dielectric material 70. Again, in an embodiment, the dummy gate electrodes are etched to remove another portion that is about 10 to about 15 percent of the initial height of the dummy gate electrode from a top surface 74 of the dummy gate electrode. In another embodiment, about 5 to about 20 nm is removed from the top surface of the dummy gate electrodes 58. Referring to FIG. 9, another subsequent isotropic etch of the sidewall liners 64 then is performed so that the angle 82 between chamfered surface 84 of sidewall liners 64 and top surface 86 of dielectric material 70 is greater than after the first etch of the sidewall liners referred to with reference to FIG. 7. The etchant used to etch sidewall liners 64 can be the same as used during the etching process described above with reference to FIG. 7 or can be another etchant that has very high selectivity for the materials that form the dummy gate electrodes 58 and the dielectric material 70.

It will be appreciated that the etching of the dummy gate electrodes 58 and the subsequent etching of sidewall liners 64 can be repeated any number of times until the sidewall liners 64 have achieved a desired chamfered profile. In an exemplary embodiment, after one or more cycles of etching the dummy gate electrodes and subsequent etching of the sidewall liners, the angle 82, as illustrated in FIGS. 7 and 9, is in the range of about 30 to about 60 degrees, for example, about 45 degrees.

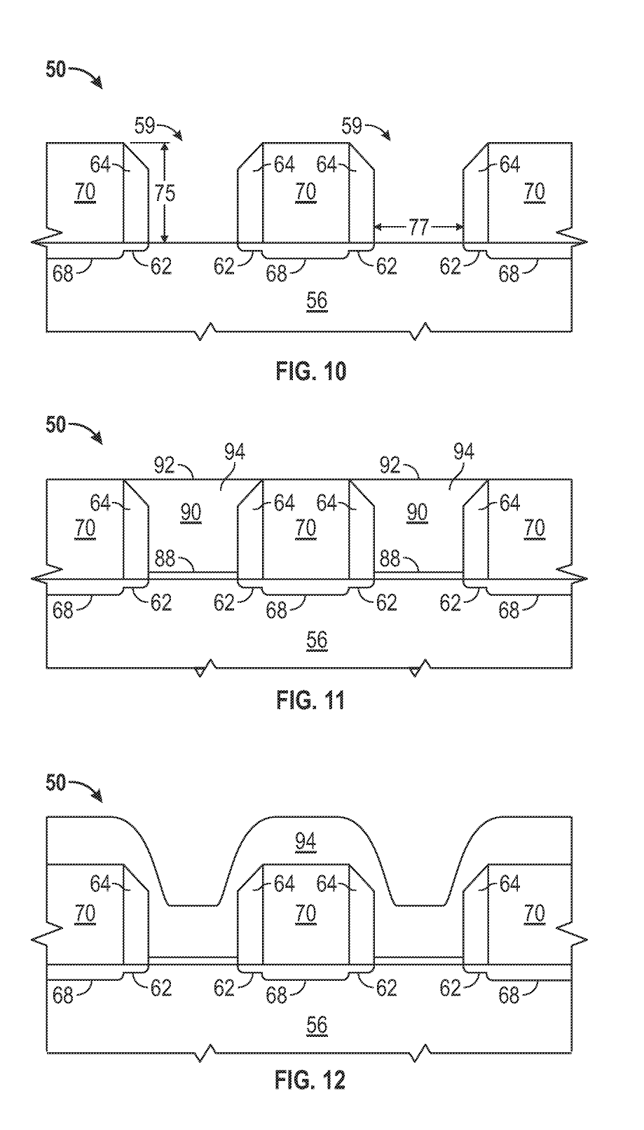

After the sidewall liners have attained the desired chamfered profile, dummy gate electrode 58 and dummy gate insulator 60 are removed to leave an opening 59, as illustrated in FIG. 10. In an embodiment, the opening has a high aspect ratio, that is, in the range of no less than about 2.5:1, such as, for example, about 2.5:1 to about 5:1. As used herein, “aspect ratio” means the height of the opening, indicated by double-headed arrow 75 to the width of the opening, indicated by double-headed arrow 77. After removing the dummy gate structure, a permanent gate insulator 88 is formed in opening 59, as illustrated in FIG. 11. The permanent gate insulator can be, for example, a silicon oxide or a high dielectric constant (“high-k”) material such as an oxide of hafnium, or a combination of silicon oxide and high-k material. A permanent gate electrode 90 then is formed by depositing a metal 94, for example, aluminum, overlying the permanent gate insulator 88 and removing excess metal, such as by CMP, to form permanent gate structures 92. Thus, the sidewall liners with a chamfered profile serve as a funnel funneling the metal of the permanent gate electrode into the narrow opening 59. Because the narrow opening 59 has a high aspect ratio, funneling the metal 94 into the opening allows for a “bottom up” filling that prevents the creation of voids during filling, as illustrated in FIG. 12.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention. It being understood that various changes may be made in the function and arrangement of elements described in an exemplary embodiment without departing from the scope of the invention as set forth in the appended claims.

What is claimed is:

1. A method for fabricating an integrated circuit, the method comprising:
forming a dummy gate electrode overlying a semiconductor substrate;
forming a liner on sidewalls of the dummy gate electrode;
depositing a dielectric material overlying the dummy gate electrode, the liner, and the semiconductor substrate;
exposing the dummy gate electrode by chemical mechanical planarization;
removing a portion of the dummy gate electrode;
isotropically etching the liner such that the liner has a chamfered surface;
removing a remainder of the dummy gate electrode to form an opening; and
filling the opening with a metal.

2. The method of claim 1, wherein the chamfered surface forms an angle with a top surface of the dielectric material that is in a range of about 30 to about 60 degrees.

3. The method of claim 1, wherein the chamfered surface forms an angle with a top surface of the dielectric material, and further comprising repeating removing a portion of the dummy gate electrode and isotropically etching until the angle is in a range of about 30 to about 60 degrees.

4. The method of claim 3, further comprising repeating removing a portion of the dummy gate electrode and isotropically etching until the angle is about 45 degrees.

5. The method of claim 1, wherein removing the remainder of the dummy gate electrode to form the opening comprises forming the opening having an aspect ratio no less than 2.5:1.

6. The method of claim 1, wherein filling the opening with the metal comprises filing the opening with aluminum.

7. The method of claim 1, wherein removing a portion of the dummy gate electrode comprises removing about 10 to about 15 percent from an initial thickness of the dummy gate electrode.

8. The method of claim 1, wherein removing a portion of the dummy gate electrode comprises removing about 5 to 20 nanometers from an initial thickness of the dummy gate electrode.

9. A method for fabricating an integrated circuit, the method comprising:
providing a dielectric layer overlying a semiconductor substrate, wherein the dielectric layer has an opening with sidewalls, wherein a sacrificial material is positioned within the opening, and wherein a liner is interposed between the sidewalls of the opening and the sacrificial material;
removing a portion of the sacrificial material;
etching the liner so that the liner has a chamfered surface;
removing a remainder of the sacrificial material leaving a second opening; and
depositing a permanent material in the second opening.

10. The method of claim 9, wherein the chamfered surface forms an angle with a top surface of the dielectric layer that is in a range of about 30 to about 60 degrees.

11. The method of claim 9, wherein the chamfered surface forms an angle with a top surface of the dielectric layer, and further comprising repeating removing a portion of the sacrificial material and etching the liner until the angle is in a range of about 30 to about 60 degrees.

12. The method of claim 11, further comprising repeating removing a portion of the sacrificial material and etching the liner until the angle is about 45 degrees.

13. The method of claim 9, wherein removing the remainder of the sacrificial material leaving the second opening comprises forming the second opening having an aspect ratio no less than 2.5:1.

14. The method of claim 9, wherein depositing the permanent material comprises depositing a metal in the second opening.

15. The method of claim 9, wherein removing a portion of the sacrificial material comprises removing about 10 to about 15 percent from an initial thickness of the sacrificial material.

16. The method of claim 9, wherein removing a portion of the sacrificial material comprises removing about 5 to 20 nanometers from an initial thickness of the sacrificial material.

17. A method for fabricating an integrated circuit, the method comprising:
forming a dummy gate electrode overlying a semiconductor substrate;
forming a liner on sidewalls of the dummy gate electrode;
depositing a dielectric material overlying the dummy gate electrode, the liner, and the semiconductor substrate;
exposing the dummy gate electrode by chemical mechanical planarization;
removing a portion of the dummy gate electrode;
forming a chamfered surface of the liner;
removing a remainder of the dummy gate electrode to form an opening; and
forming a permanent gate electrode in the opening,
wherein after removing the remainder of the dummy gate electrode and before forming the permanent gate electrode, the chamfered surface of the liner forms an angle with a top surface of the dielectric material that is in a range of about 30 to about 60 degrees.

18. The method of claim 17, the step of forming the chamfered surface of the liner comprises forming the chamfered surface so that the angle is about 45 degrees.

19. The method of claim 17, further comprising repeating removing a portion of the dummy gate electrode and forming a chamfered surface before removing the remainder of the dummy gate electrode.

20. The method of claim 17, wherein removing a portion of the dummy gate electrode comprises removing about 10 to about 15 percent from an initial thickness of the dummy gate electrode.
